(19) United States
(12) Patent Application Publication
(10) Pub. No.: US 2024/0234655 A9
(43) Pub. Date: Jul. 11, 2024

(54) U-DISPLAY STRUCTURE WITH QD COLOR CONVERSION AND METHODS OF MANUFACTURE

(71) Applicant: Applied Materials, Inc., Santa Clara, CA (US)

(72) Inventors: Zhiyong LI, San Jose, CA (US); Sivapackia GANAPATHIAPPAN, Los Altos, CA (US); Mingwei ZHU, San Jose, CA (US); Nag B. PATIBANDLA, Pleasanton, CA (US); Hou T. NG, Campbell, CA (US); Lisong XU, Santa Clara, CA (US); Ding KAI, Santa Clara, CA (US); Kulandaivelu SIVANANDAN, Santa Clara, CA (US)

(21) Appl. No.: 18/490,847

(22) Filed: Oct. 20, 2023

Related U.S. Application Data
(60) Provisional application No. 63/380,775, filed on Oct. 25, 2022.

(51) Int. Cl. H01L 33/60; H01L 25/16

(52) U.S. Cl. CPC H01L 33/60; H01L 25/167; H01L 2933/0058

(57) ABSTRACT

Embodiments of the present disclosure generally relate to LED pixels and methods of fabricating LED pixels. A device includes a backplane, at least three LEDs disposed on the backplane, subpixel isolation (SI) structures disposed defining wells of at least three subpixels, a reflection material is disposed on sidewalls and a top surface of the SI structures, at least three of the subpixels have a color conversion material disposed in the wells, an encapsulation layer disposed over the subpixel isolation structures and the subpixels, a light filter layer disposed over the encapsulation layer and micro-lenses disposed over the light filter layer and over each of the wells of the subpixels.

### RELATED APPLICATIONS

This application claims benefit of and priority to U.S. Application No. 63/380,775, filed Oct. 25, 2022, which are herein incorporated in its entirety by reference for all purposes.

### BACKGROUND

### Field

Embodiments of the present disclosure generally relate to LED pixels and methods of fabricating LED pixels.

### Description of the Related Art

A light emitting diode (LED) panel uses an array of LEDs, with individual LEDs providing the individually controllable pixel elements. Such an LED panel can be used for a computer, touch panel device, personal digital assistant (PDA), cell phone, television monitor, and the like.

An LED panel that uses micron-scale LEDs based on III-V semiconductor technology (also called micro-LEDs) would have a variety of advantages as compared to OLEDs, e.g., higher energy efficiency, brightness, and lifetime, as well as fewer material layers in the display stack which can simplify manufacturing. However, there are challenges to fabrication of micro-LED panels. Micro-LEDs having different color emission (e.g., red, green and blue pixels) need to be fabricated on different substrates through separate processes. Integration of the multiple colors of micro-LED devices onto a single panel requires a pick-and-place step to transfer the micro-LED devices from their original donor substrates to a destination substrate. This often involves modification of the LED structure or fabrication process, such as introducing sacrificial layers to ease die release. In addition, stringent requirements on placement accuracy (e.g., less than 1 μm) limit either the throughput, the final yield, or both.

An alternative approach to bypass the pick-and-place step is to selectively deposit color conversion agents (e.g., quantum dots, nanostructures, photoluminescent materials, or organic substances) at specific pixel locations on a substrate fabricated with monochrome LEDs. The monochrome LEDs can generate relatively short wavelength light, e.g., purple or blue light, and the color conversion agents can convert this short wavelength light into longer wavelength light, e.g., red or green light for red or green pixels. The selective deposition of the color conversion agents can be performed using high-resolution shadow masks or controllable inkjet or aerosol jet printing.

### SUMMARY

In one embodiment, a device is provided. The device includes a backplane, LEDs disposed over the backplane, subpixel isolation (SI) structures disposed over the LEDs defining wells of subpixels, each well including a respective LED between adjacent SI structures, the subpixels have a different color conversion material disposed in the wells, and micro-lenses disposed over each of the wells of the subpixels, the micro-lenses including a light filter material.

In another embodiment, a device is provided. The device includes a backplane, LEDs disposed over the backplane, subpixel isolation (SI) structures disposed over the LEDs defining wells of subpixels, each well including a respective LED between adjacent SI structures, the subpixels have a different color conversion material disposed in the wells, an encapsulation layer over SI structures and the subpixels, a light filter layer disposed over the encapsulation layer, a second passivation layer disposed on the light filter layer, and micro-lenses disposed over the light filter layer and over each of the wells of the subpixels.

In another embodiment, a device is provided. The device includes a backplane, LEDs disposed over the backplane, subpixel isolation (SI) structures disposed over the LEDs defining wells of subpixels, each well including a respective LED between adjacent SI structures, the subpixels have a different color conversion material disposed in the wells, wherein the device is made by a process including: disposing a light filter layer over the wells and SI structures, and performing a nanoimprint lithography process to form micro-lenses from the light filter layer over the subpixels.

In another embodiment, a device is provided. The device includes a backplane, LEDs disposed over the backplane, subpixel isolation (SI) structures disposed over the LEDs defining wells of subpixels, each well including a respective LED between adjacent SI structures, the subpixels have a different color conversion material disposed in the wells, an encapsulation layer over SI structures and the subpixels, a light filter layer disposed over the encapsulation layer, and a second passivation layer disposed on the light filter layer, wherein the device is made by a process including: disposing a resist on the second passivation layer, patterning the resist to form portions over the subpixels, and performing one of a gray-scale process, a thermal reflow process, or a nanoimprint lithography process to form micro-lenses from the portions of the resist over the subpixels.

In yet another embodiment, a method is provided. The method includes depositing a reflection material is deposited at an angle over a backplane, the backplane having LEDs disposed thereover, subpixel isolation (SI) structures disposed over the LEDs defining wells of subpixels, each well including a respective LED between adjacent SI structures, the reflection material is deposited on one sidewall and a top surface of SI structures and rotating the backplane at least 90 degrees and depositing the reflection material at the angle.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a pixel having a first microlens arrangement according to embodiments.

FIG. 1B is a schematic, cross-sectional view of a pixel having a second microlens arrangement according to embodiments.

FIG. 2 is a flow diagram of a method of forming a reflection material on the subpixel isolation structures according to embodiments.

FIGS. 3A-3E are schematic, cross-sectional views of a backplane during the method 200 according to embodiments.

FIG. 4 is a flow diagram of a method 400 of forming subpixels according to embodiments.

FIGS. 5A-5C are schematic, cross-sectional views of a backplane during the method 400 according to embodiments.

FIG. 6 is a flow diagram of a method 400 of forming subpixels according to embodiments.

FIGS. 7A-7C are schematic, cross-sectional views of a backplane during the method 600 according to embodiments.

FIGS. 8A and 8B are cross-sectional views of a backplane during formation of a first microlens arrangement according to embodiments.

FIG. 8C is a cross-sectional view of a backplane during formation of a second microlens arrangement according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to LED pixels and methods of fabricating LED pixels. A device includes a backplane, at least three LEDs disposed on the backplane, subpixel isolation (SI) structures disposed defining wells of at least three subpixels, a reflection material is disposed on sidewalls and a top surface of the SI structures, at least three of the subpixels have a color conversion material disposed in the wells, an encapsulation layer disposed over the subpixel isolation structures and the subpixels, a light filter layer disposed over the encapsulation layer and micro-lenses disposed over the light filter layer and over each of the wells of the subpixels.

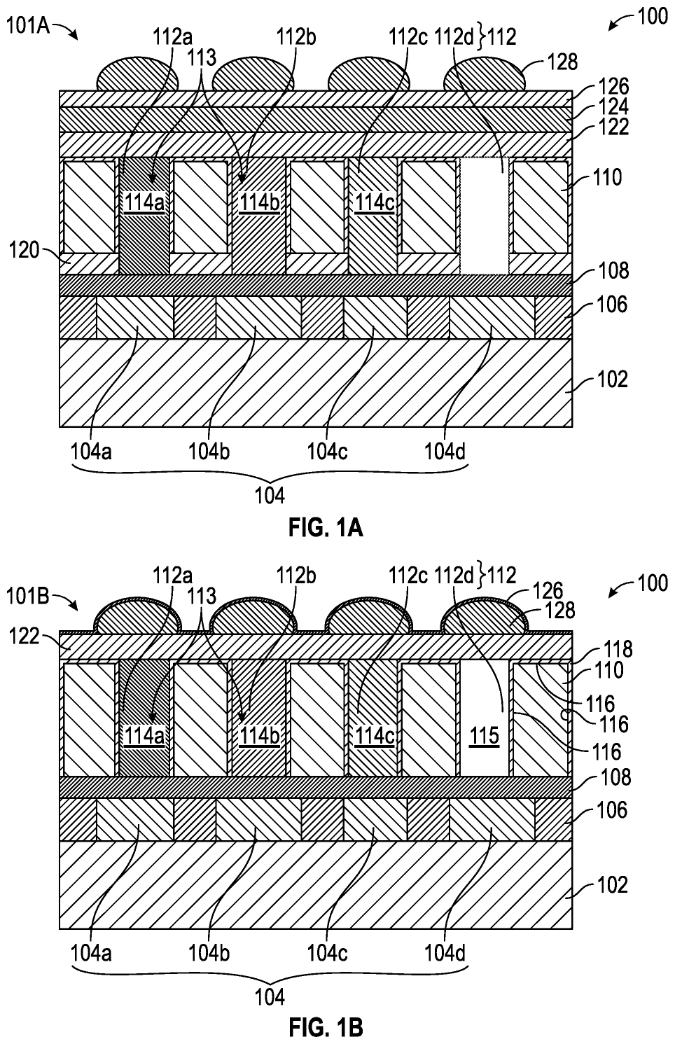

FIG. 1A is a schematic, cross-sectional view of a pixel 100 having a first microlens arrangement 101A. FIG. 1B is a schematic, cross-sectional view of a pixel 100 having a second microlens arrangement 101B. The pixel 100 includes at least three LEDs 104 disposed on a backplane 102. An isolation material 106 may be disposed between the LEDs 104. The LEDs 104 are integrated with backplane circuitry so that each LED 104 can be individually addressed. For example, the circuitry of the backplane 102 can include a TFT active matrix array with a thin-film transistor and a storage capacitor (not illustrated) for each LED, column address and row address lines, column and row drivers, to drive the LEDs 104. Alternatively, the LEDs 104 can be driven by a passive matrix in the backplane circuitry. The backplane 102 can be fabricated using conventional CMOS processes. Each LED configured to emit UV light in a first wavelength range. The UV light may be white light. The LEDs 104 may be micro-LEDs.

A passivation layer 108 is disposed over, and in some embodiments directly on, the LEDs 104. Subpixel isolation (SI) structures 110 are disposed over, and in some embodiments (as shown in FIG. 1B) on, the passivation layer 108. The adjacent subpixel isolation structures define the respective well 113 of at least three subpixels 112. The subpixels 112 include a red subpixel 112a with a red color conversion material disposed in the well 113 of the red subpixel 112a, a green subpixel 112b with a green color conversion material disposed in the well 113 of the green subpixel 112b, and a blue subpixel 112c with a blue color conversion material disposed in the well 113 of the blue subpixel 112c. When a LED 104a of the red subpixel 112a is turned on the red color conversion material will convert the light emitted from LED 104a into red light. When a LED 104c of the blue subpixel 112c is turned on the blue color conversion material will convert the light emitted from LED 104c into blue light. In one embodiment, the pixel 100 includes a fourth subpixel 112d. As shown in FIG. 1A, the fourth subpixel 112d does not include a color conversion material, i.e., color-conversion-layer-free. As shown in FIG. 1B, the fourth subpixel 112d includes a sacrificial material 115. In other embodiments, the at least three subpixels 112 include the same color conversion material. The fourth subpixel 112d may be later filled with a color conversion material.

The subpixel isolation structures 110 include a photoresist material, such as an epoxy-based resist. The photoresist material is a negative photoresist. The exposed surfaces 116, i.e., the sidewalls and top surface, of the subpixel isolation structures 110 have a reflection material 118 disposed thereon. The reflection material 118 on the exposed surfaces 116 provide for reflection of the emitted light to contain the converted light to the respective subpixel in order to collimate the light to the display. The reflection material 118 includes, but is not limited to, aluminum, silver, combinations thereof, or the like. In one embodiment, as shown in FIG. 1A, an antireflection material 120 is disposed between the subpixel isolation structures 110 and the passivation layer 108. The antireflection material 120 may include chromium nitride (CrN).

An encapsulation layer 122 is disposed over the subpixel isolation structures 110 and the subpixels 112. As shown in FIG. 1A, the first microlens arrangement 101A includes a light filter layer 124 disposed over the encapsulation layer 122. A second passivation layer 126 is disposed on the light filter layer 124 with micro-lenses 128 disposed on the second passivation layer 126 and over each of the wells 113 of the subpixels 112. The light filter layer 124 can be selective for photons of certain wavelengths. In some embodiments, the light filter layer 124 is a UV blocking layer, a UV reflecting layer, a blue light blocking layer, a blue light reflecting layer, or combinations thereof. The light filter layer 124 may include a UV blocking material, a UV reflecting material, a blue light blocking material, a blue light reflecting material, or combinations thereof. The second passivation layer 126 may include silicon nitride. As shown in FIG. 1B, the second microlens arrangement 101B includes the micro-lenses 128 disposed on the encapsulation layer 122 and over each of the wells 113 of the subpixels 112. The second passivation layer 126 is disposed on the micro-lenses 128. The micro-lenses 128 of the second microlens arrangement 101B include a resist material, such as a photoresist material that blocks UV light.

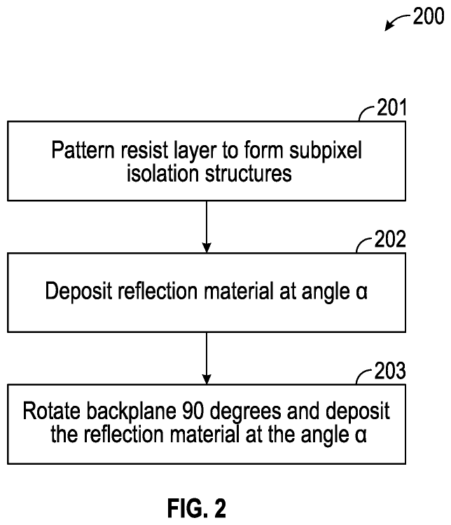

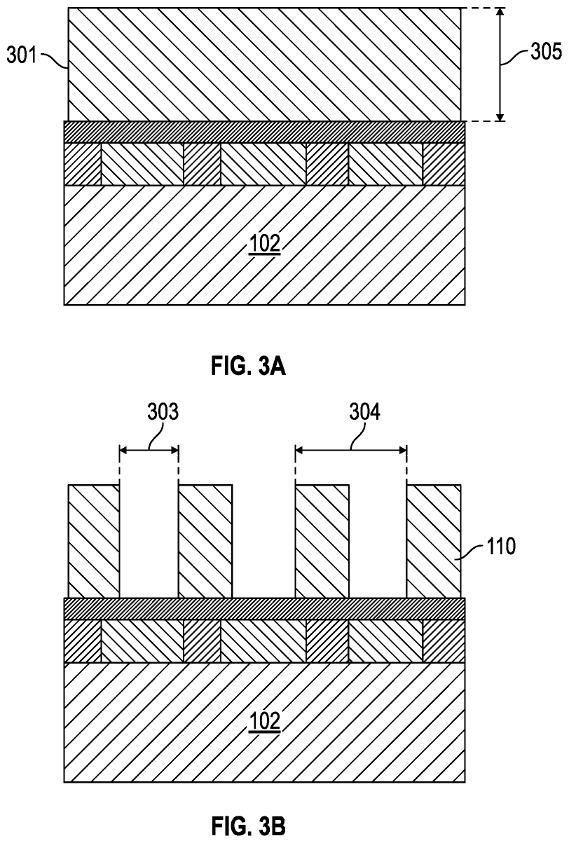

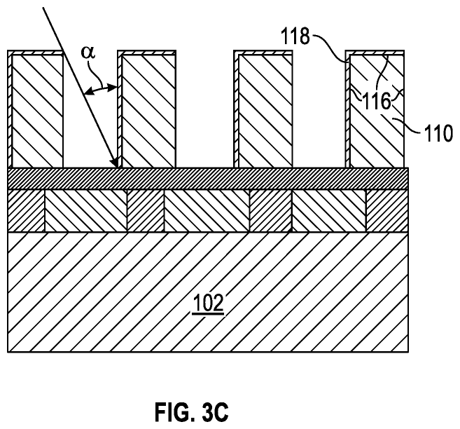

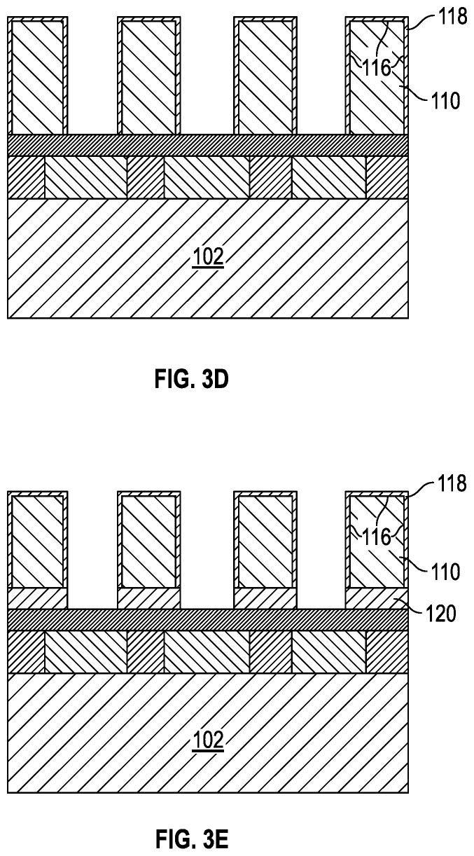

FIG. 2 is a flow diagram of a method 200 of forming a reflection material 118 on the subpixel isolation structures 110. FIGS. 3A-3E are schematic, cross-sectional views of the backplane 102 during the method 200. At operation 201, as shown in FIGS. 3A and 3B, a resist layer 301 is patterned to form the subpixel isolation structures 110. The resist layer may be patterned by a photoresist patterning process. The subpixel isolation structures 110 may have a width 303 of about 1 μm to about 4 μm, such as 2 μm to 3 μm. The subpixel isolation structures 110 may have a pitch 304 of about 2 μm to about 6 μm, such as about 4 μm. The subpixel isolation structures 110 may have a thickness 305 of about 2 μm to about 12 μm, such as 5 μm to 10 μm. In some embodiments, as shown in FIG. 3E, an antireflection material 120 is disposed between the subpixel isolation structures 110 and the passivation layer 108. When the resist layer 301 is patterned, residual portions of the antireflection material 120 is disposed between the subpixel isolation structures 110 are removed. The antireflection material 120 assists in defining the subpixel isolation structures 110 during photoresist patterning. At operation 202, as shown in FIG. 3C, the reflection material 118 is deposited at an angle α. The deposition process includes PVD. The angle α may be between 10 degrees and 35 degrees. Of the exposed surfaces 116, the reflection material 118 is deposited on one sidewall and the top surface of the subpixel isolation structures 110. At operation 203, the backplane 102 is rotated at least 90 degrees and the reflection material 118 is deposited at the angle α. For four sided subpixel isolation structures 110, the backplane 102 is rotated 90 degrees and the reflection material 118 is deposited three additional times. Operation 203 is repeated twice such that the reflection material 118 is deposited on the four sidewalls and top surface of the subpixel isolation structures 110, as shown in FIGS. 3D and 3E. For circular wells 113, the backplane 102 is rotated 360 degrees and the reflection material 118 is deposited.

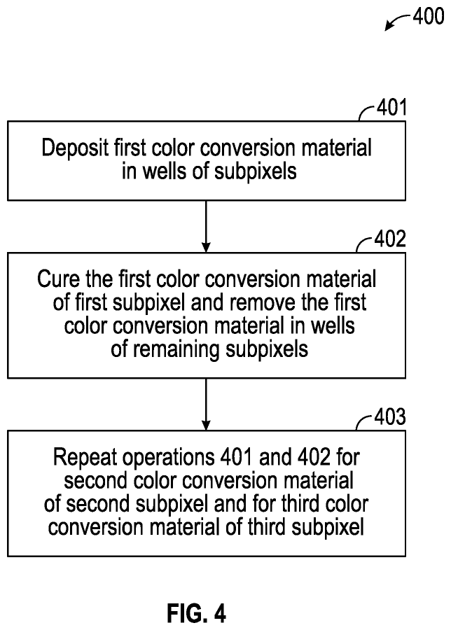

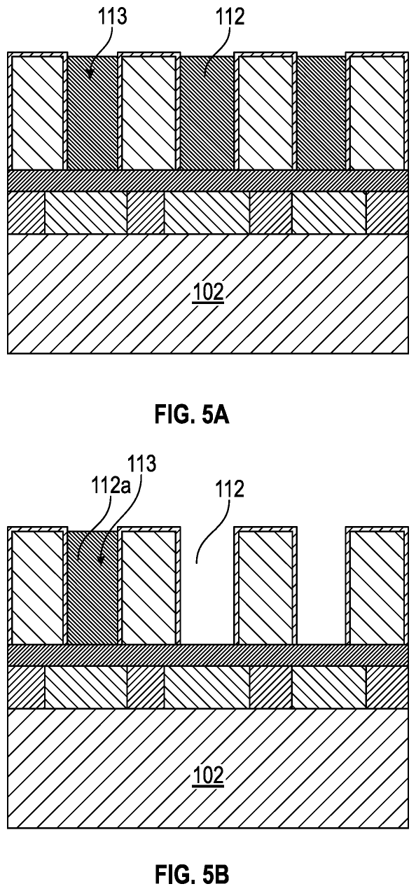

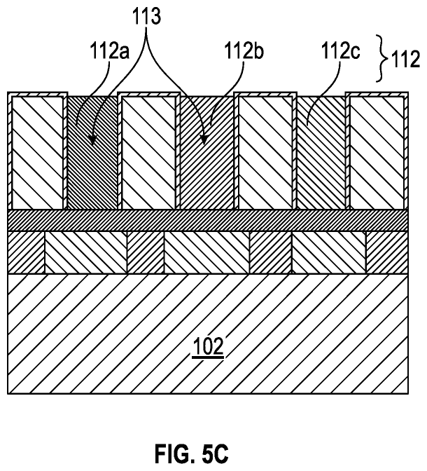

FIG. 4 is a flow diagram of a method 400 of forming the subpixels 112. FIGS. 5A-5C are schematic, cross-sectional views of the backplane 102 during the method 400 of forming the subpixels 112. At operation 401, as shown in FIG. 5A, a first color conversion material is deposited in each of the wells 113 of the subpixels 112. Operation 401 is performed after the method 200. In one embodiment, the first color conversion material is a red color conversion material for the red subpixel 112a. At operation 402, as shown in FIG. 5B, the first color conversion material of a first subpixel is cured and the first color conversion material in wells of the remaining subpixels is removed. The first subpixel may correspond to the red subpixel 112a. At operation 403, as shown in FIG. 5C, operations 401 and 402 are repeated for a second color conversion material of a second subpixel and for a third color conversion material of a third subpixel. The first, second, and third conversion materials are cured via laser curing and are removed via washing. In one embodiment, the second color conversion material is a green color conversion material for the green subpixel 112b and the third color conversion material is a blue color conversion material for the blue subpixel 112c. Operations 401 and 402 may be repeated for the fourth subpixel 112d.

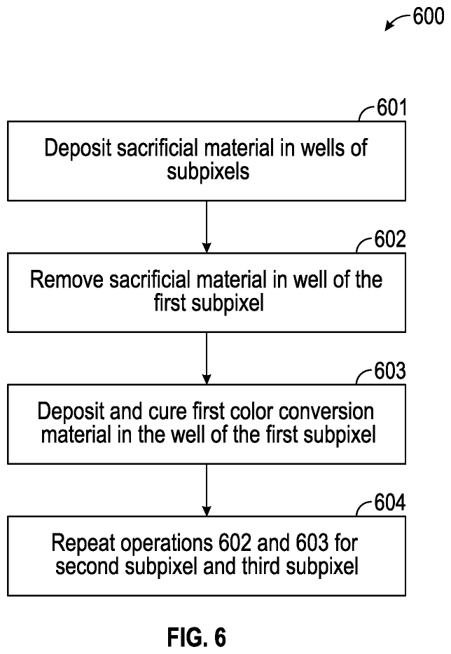

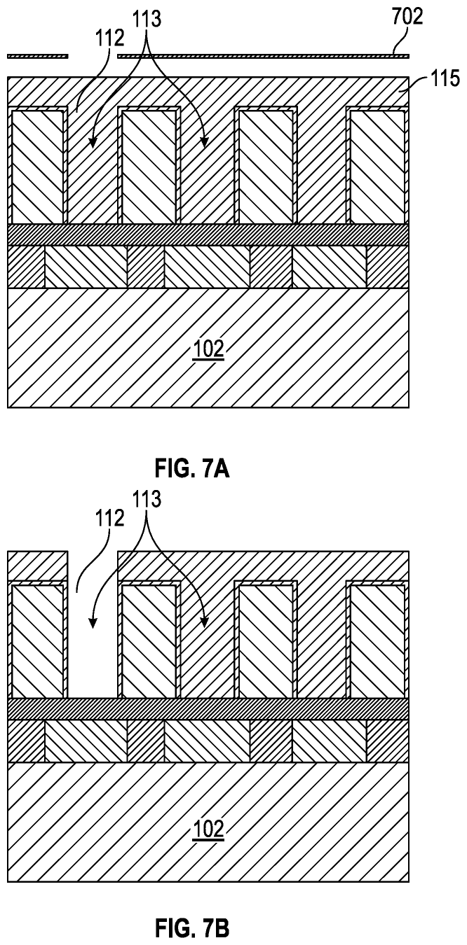

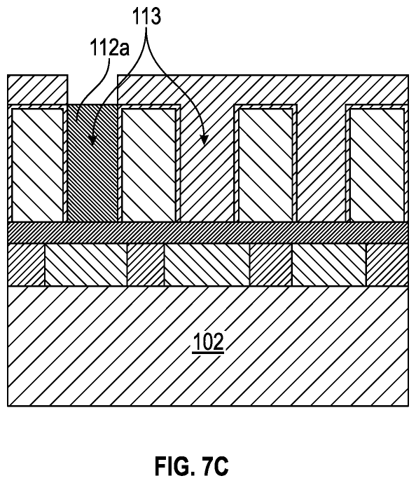

FIG. 6 is a flow diagram of a method 600 of forming the subpixels 112. FIGS. 7A-7C are schematic, cross-sectional views of the backplane 102 during the method 600 of forming the subpixels 112. At operation 601, a sacrificial material 115 is deposited in each of the wells 113 of the subpixels 112. Operation 601 is performed after the method 200. At operation 602, as shown in FIGS. 7A and 7B, the sacrificial material 115 in a well of the first subpixel is removed. The sacrificial material 115 is a positive photoresist. The sacrificial material 115 may be deposited via spin coating. The sacrificial material 115 may be removed exposing the well of the first subpixel to light through an opening with the mask 702 in developing the sacrificial material 115. At operation 603, as shown in FIG. 7C, a first color conversion material is deposited in the well of the first subpixel and is cured. In one embodiment, the first color conversion material is a red color conversion material and the first subpixel is the red subpixel 112a. At operation 604, as shown in FIG. 5C, operations 602 and 603 are repeated a second subpixel and a third subpixel. The first, second, and third conversion material is cured via laser curing. In one embodiment, the second color conversion material is a green color conversion material for the green subpixel 112b and the third color conversion material is a blue color conversion material for the blue subpixel 112c. Operations 602 & 603 may be repeated for the fourth subpixel 112d.

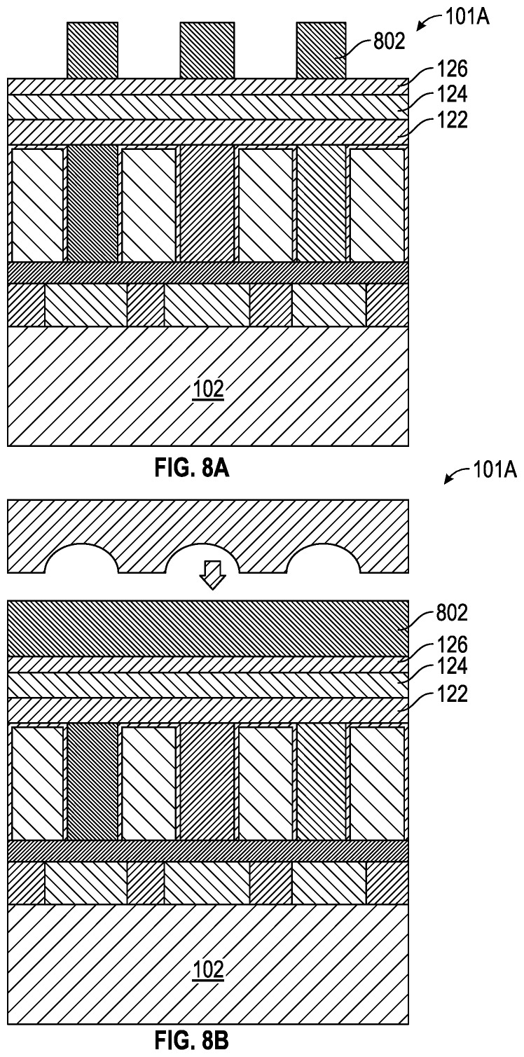

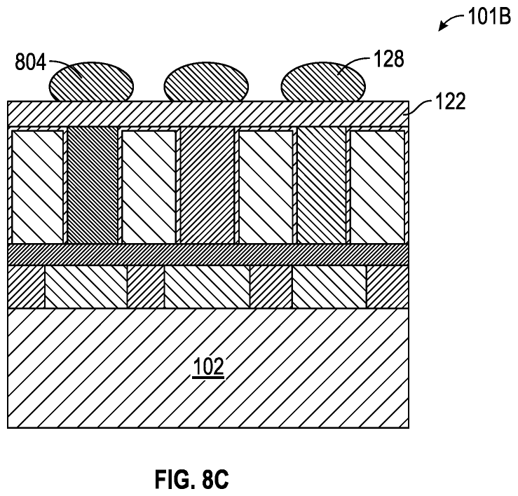

To form the first microlens arrangement 101A of the pixel 100, an encapsulation layer 122 is disposed over the subpixel isolation structures 110 and the subpixels 112. A light filter layer 124 is disposed over the encapsulation layer 122. A second passivation layer 126 is disposed on the light filter layer 124. The light filter layer 124 can be selective for photons of certain wavelengths. In some embodiments, the light filter layer 124 is a UV blocking layer, a UV reflecting layer, a blue light blocking layer, a blue light reflecting layer, or combinations thereof. The light filter layer 124 may include a UV blocking material, a UV reflecting material, a blue light blocking material, a blue light reflecting material, or combinations thereof. FIGS. 8A and 8B are cross-sectional views of the backplane 102 during the formation of the first microlens arrangement 101A. A resist 802 is disposed on the second passivation layer 126. In one embodiment, the resist 802 is patterned such that the resist 802 remains over each of the wells 113 of the subpixels 112, as shown in FIG. 8A. The resist 802 is gray-scale patterned or exposed to a thermal reflow process to form the micro-lenses 128, as shown in FIG. 1A. In another embodiment, resist 802 is imprinted with the stamp (e.g., via nanoimprint lithography), as shown in FIG. 8B, to form the micro-lenses 128, as shown in FIG. 1A.

FIG. 8C is a cross-sectional view of the backplane 102 during the formation of the second microlens arrangement 101B. To form the second microlens arrangement 101B of the pixel 100, an encapsulation layer 122 is disposed over the subpixel isolation structures 110 and the subpixels 112. A resist 804 is disposed on the encapsulation layer 122. The resist 804 is imprinted with a stamp to form the micro-lenses 128, as shown in FIG. 1B. The resist 804 includes a light filter material. In some embodiments, the light filter material includes a UV blocking material, a UV reflecting material, a blue light blocking material, a blue light reflecting material, or combinations thereof. The second passivation layer 126 is disposed over the micro-lenses 128.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a backplane;
LEDs disposed over the backplane;
subpixel isolation (SI) structures disposed over the LEDs defining wells of subpixels, each well including a respective LED between adjacent SI structures, the subpixels have a different color conversion material disposed in the wells; and
micro-lenses disposed over each of the wells of the subpixels, the micro-lenses including a light filter material.

2. The device of claim 1, wherein the light filter layer is a UV blocking layer, a UV reflecting layer, a blue light blocking layer, or a blue light reflecting layer.

3. The device of claim 1, wherein an antireflection material is disposed between the SI structures and the backplane.

4. The device of claim 1, wherein an encapsulation layer is disposed under the micro-lenses and over SI structures and the subpixels.

5. The device of claim 1, wherein a second passivation layer is disposed on the micro-lenses.

6. The device of claim 1, wherein a reflection material is disposed on sidewalls and a top surface of the SI structures.

7. The device of claim 1, further comprising four subpixels, wherein a respective well of a fourth subpixel includes a sacrificial material or a color conversion material.

8. A device, comprising:
a backplane;
LEDs disposed over the backplane;
subpixel isolation (SI) structures disposed over the LEDs defining wells of subpixels, each well including a respective LED between adjacent SI structures, the subpixels have a different color conversion material disposed in the wells;
an encapsulation layer over SI structures and the subpixels;
a light filter layer disposed over the encapsulation layer;
a second passivation layer disposed on the light filter layer; and
micro-lenses disposed over the light filter layer and over each of the wells of the subpixels.

9. The device of claim 8, wherein the light filter layer is a UV blocking layer, a UV reflecting layer, a blue light blocking layer, or a blue light reflecting layer.

10. The device of claim 8, wherein an antireflection material is disposed between the SI structures and the backplane.

11. The device of claim 8, wherein at least three of the subpixels have a different color conversion material.

12. The device of claim 8, further comprising four subpixels, wherein a respective well of a fourth subpixel includes a sacrificial material or a color conversion material.

13. A device comprising a backplane, LEDs disposed over the backplane, subpixel isolation (SI) structures disposed over the LEDs defining wells of subpixels, each well including a respective LED between adjacent SI structures, the subpixels have a different color conversion material disposed in the wells, wherein the device is made by a process comprising:
disposing a light filter layer over the wells and SI structures; and
performing a nanoimprint lithography process to form micro-lenses from the light filter layer over the subpixels.

14. The device of claim 13, wherein an encapsulation layer is disposed under the micro-lenses and over SI structures and the subpixels.

15. The device of claim 13, wherein a second passivation layer is disposed on the micro-lenses.

16. The device of claim 13, wherein a reflection material is disposed on sidewalls and a top surface of the SI structures.

17. The device of claim 13, further comprising four subpixels, wherein a respective well of a fourth subpixel includes a sacrificial material or a color conversion material.

18. A device comprising a backplane, LEDs disposed over the backplane, subpixel isolation (SI) structures disposed over the LEDs defining wells of subpixels, each well including a respective LED between adjacent SI structures, the subpixels have a different color conversion material disposed in the wells, an encapsulation layer over SI structures and the subpixels, a light filter layer disposed over the encapsulation layer, and a second passivation layer disposed on the light filter layer, wherein the device is made by a process comprising:
disposing a resist on the second passivation layer;
patterning the resist to form portions over the subpixels; and
performing one of a gray-scale process, a thermal reflow process, or a nanoimprint lithography process to form micro-lenses from the portions of the resist over the subpixels.

19. The device of claim 18, wherein a reflection material is disposed on sidewalls and a top surface of the SI structures.

20. The device of claim 19, further comprising four subpixels, wherein a respective well of a fourth subpixel includes a sacrificial material or a color conversion material.

21. A method, comprising:
depositing a reflection material is deposited at an angle over a backplane, the backplane having LEDs disposed thereover, subpixel isolation (SI) structures disposed over the LEDs defining wells of subpixels, each well including a respective LED between adjacent SI structures, the reflection material is deposited on one sidewall and a top surface of SI structures; and
rotating the backplane at least 90 degrees and depositing the reflection material at the angle.

22. The method of claim 21, further comprising:
depositing a first color conversion material in a first well of a first subpixel, a second well of a second subpixel, and a third well of a third subpixel;
curing the first color conversion material in the first well;
removing the first color conversion material in the second well and the third well;
depositing a second color conversion material in the second well of the second subpixel and the third well of the third subpixel;
curing the second color conversion material in the second well;
removing the second color conversion material in the third well;
depositing a third color conversion material in the third well of the third subpixel; and
curing the third color conversion material in the third well.

23. The method of claim 21, further comprising:
depositing a sacrificial material in a first well of a first subpixel, a second well of a second subpixel, and a third well of a third subpixel;
exposing the sacrificial material in the first well to light through an opening of a mask;
removing the sacrificial material that was exposed in the first well;
depositing a first color conversion material in the first well;
exposing the sacrificial material in the second well to light through the opening of the mask;
depositing a second color conversion material in the second well;
exposing the sacrificial material in the third well to light through the opening of the mask; and
depositing a third color conversion material in the third well.

24. The method of claim 21, further comprising:
repeating rotating the backplane 90 degrees and the depositing the reflection material twice such that the reflection material is deposited on four sidewalls and the top surface of the SI structures.

25. The method of claim 21, further comprising:
disposing an encapsulation layer over SI structures and the subpixels;
disposing a light filter layer disposed over the encapsulation layer;
disposing a second passivation layer disposed on the light filter layer;
disposing a resist on the second passivation layer;
patterning the resist to form portions over the subpixels; and
performing one of a gray-scale process, a thermal reflow process, or a nanoimprint lithography process to form micro-lenses from the portions of the resist over the subpixels.
